(19) United States
(12) Patent Application Publication
(10) Pub. No.: US 2011/0235453 A1
(43) Pub. Date: Sep. 29, 2011

(54) FUSE CIRCUIT AND REPAIR CONTROL CIRCUIT USING THE SAME

(76) Inventors: Sung-Soo CHI, Gyeonggi-do (KR); Ki-Chang Kwean, Gyeonggi-do (KR)

(21) Appl. No.: 12/815,899

(22) Filed: Jun. 15, 2010

(30) Foreign Application Priority Data
Mar. 29, 2010 (KR) 10-2010-0028159

(51) Int. Cl. G11C 17/16; H01H 37/76

(52) U.S. Cl. 365/225.7; 327/525; 365/200

(57) ABSTRACT

A fuse circuit includes a fuse driving unit, a separation/connection unit, a voltage equalization unit, and a latching unit. The fuse driving unit is configured to drive an output terminal in response to a fuse reset signal, depending on data programmed in a fuse. The separation/connection unit is disposed between the fuse and the output terminal and configured to separate or connect the fuse from or to the output terminal in response to a control signal. The voltage equalization unit is configured to equalize both ends of the fuse to the same voltage in response to the control signal. The latching unit is configured to latch and output the output terminal driven by the fuse driving unit.

### CROSS-REFERENCE TO RELATED APPLICATIONS

The present application claims priority of Korean Patent Application No. 10-2010-0028159, filed on Mar. 29, 2010, which is incorporated herein by reference in its entirety.

### BACKGROUND OF THE INVENTION

Exemplary embodiments of the present invention relate to a semiconductor design technology, and more particularly, to a fuse circuit.

In general, semiconductor memory devices, including a double data rate synchronous DRAM (DDR SDRAM), have a variety of circuits provided therein to perform various operations. One of the circuits is a fuse circuit.

FIG. 1 is a circuit diagram of a known fuse circuit.

Referring to FIG. 1, the fuse circuit includes a fuse driving unit 110 and an output unit 120.

The fuse driving unit 110 is configured to drive a second node B in response to a fuse reset signal FSE, depending on data programmed in a fuse F. The fuse driving unit 110 includes a first PMOS transistor PM1, a fuse F, and a first NMOS transistor NM1, which are connected in series between a power supply voltage (VDD) terminal and a ground voltage (VSS) terminal.

The output unit 120 is configured to drive a third node C depending on the voltage level of the second node B. The output unit 120 includes an inverter INV and a second NMOS transistor NM2 which is controlled by a feed-back signal outputted to the third node C. In other words, the output of the inverter INV is coupled to the gate of the second NMOS transistor NM2.

Meanwhile, desired data may be programmed in the fuse F. Programming a fuse refers to performing a series of operations which cut the fuse F or do not cut the fuse F. In general, a method for programming a fuse is roughly divided into an electrical cutting method and a laser cutting method. The electrical cutting method refers to a method in which an over current is applied to a target fuse to melt and cut the target fuse, and the laser cutting method refers to a method in which laser beams are used to blow and cut a target fuse. In general, since the laser cutting method is simpler than the electrical cutting method, the laser cutting method is more widely used.

FIG. 2 is a timing diagram illustrating the operation of the fuse circuit of FIG. 1. Herein, for example, the fuse reset signal FSE is a signal which is activated in response to a power-up signal, which is activated during a power-up operation of a semiconductor memory device.

Referring to FIGS. 1 and 2, the power supply voltage VDD applied from the outside of the semiconductor memory device rises to a voltage level with a constant slope when the semiconductor memory device is driven for the first time. Although not illustrated in the drawings, the power-up signal is deactivated when the power supply voltage VDD rises to a certain voltage level or more, and the fuse reset signal FSE is activated as a pulse type signal in response to the power-up signal.

A period R1 in which the fuse rest signal FSE is activated to logic ‘high’ is an initialization operation period of the second node B. In the period R1, the first NMOS transistor NM1 is turned on and the first PMOS transistor PM1 is turned off in response to the fuse reset signal FSE. Therefore, the second node B is precharged to the ground voltage VSS. At this time, the second NMOS transistor NM2 is turned on in response to an output signal of the third node C, which is obtained by inverting the signal of the second node B, and the second node B is driven to the ground voltage VSS by the second NMOS transistor NM2.

A period R2 in which the fuse reset signal FSE maintains logic ‘low’ after changing from logic ‘high’ to logic ‘low’ is a period in which the data programmed in the fuse F is outputted to the third node C. In the period R2, the first PMOS transistor PM1 is turned on and the first NMOS transistor NM1 is turned off in response to the fuse reset signal FSE. At this time, the logic levels of the first and second nodes A and B are determined depending on whether the fuse F is cut or not. That is, when the fuse F is not cut, the first and second nodes A and B become logic ‘high’ in the period R2. However, when the fuse F is cut, the first node A becomes logic ‘high’ and the second node B maintains logic ‘low’ in the period R2.

Meanwhile, as the process technology of semiconductor memory devices develops, a fuse has been significantly reduced in size, which means that a cutting region of the fuse has also been reduced. When the cutting region is reduced, a cut fuse may be easily converted into a state in which the fuse is not cut for a variety of reasons. In this case, a fuse fail may occur. For example, a fuse fail defect may be caused by an electric field formed by a voltage difference between both ends of the cut fuse. As a result of the fuse fail, the cut fuse operates like fuses which are not cut. In this case, a circuit including the fuse may malfunction.

Returning to FIGS. 1 and 2, the case in which the fuse fail occurs will be described in more detail. For convenience, the case in which the fuse F is cut will be taken as an example.

When the fuse F of FIG. 1 is cut, the voltage levels of the first and second nodes A and B are different from each other as shown in FIG. 2. That is, in the period R2 in which the fuse reset signal FSE maintains logic ‘low’, the first node A becomes logic ‘high’ corresponding to the power supply voltage VDD, and the second node B becomes logic ‘low’ corresponding to the ground voltage VSS. In this case, a voltage difference occurs between both ends of the fuse F. When this state is continuously maintained, a fuse fail may occur. As a result, although the fuse F was cut, the fuse may be converted into a state in which the fuse F is not cut, due to the voltage difference between both ends of the fuse F. Further, this fuse fail may cause the initial data programmed in the fuse F to change into different data.

Meanwhile, since such a fuse fail occurs after the fuse is cut, it is difficult to detect the fail. Furthermore, the fuse fail may reduce not only the productivity of the semiconductor memory device, but also the performance and reliability of the semiconductor memory device. In such a structure, a direct current path may be formed at the point of time when the fuse reset signal FSE changes to logic ‘low’, and unnecessary power consumption may occur.

### SUMMARY OF THE INVENTION

Exemplary embodiments of the present invention are directed to a fuse circuit which transmits data stored in a fuse at a certain time after a power-up operation and then equalizes both ends of the fuse to the same voltage.

In accordance with an exemplary embodiment of the present invention, a fuse circuit includes a fuse driving unit configured to drive an output terminal in response to a fuse reset signal, depending on data programmed in a fuse, a separation/connection unit disposed between the fuse and the output terminal and configured to separate or connect the fuse from or to the output terminal in response to a control signal, a voltage equalization unit configured to equalize both ends of the fuse to the same voltage in response to the control signal, and a latching unit configured to latch and output the output terminal driven by the fuse driving unit. The fuse circuit further comprising a control signal generation unit configured to generate the control signal in response to a power-up signal which is activated during a power-up operation.

The control signal may have a certain pulse width after a power-up operation.

The control signal may be deactivated at a certain time after the power-up operation.

A first period may correspond to the connection operation of the separation/connection unit does not overlap with a second period corresponding to the equalization operation of the voltage equalization unit.

The fuse circuit may further include a first delay unit configured to delay the control signal to output a first control signal for controlling the separation/connection unit; and a second delay unit configured to delay the control signal to output a second control signal for controlling the voltage equalization unit.

The first delay unit may receive the control signal and delays a deactivation time corresponding to the connection operation of the separation/connection unit, and the second delay unit receives the control signal and delays a deactivation time corresponding to the equalization operation of the voltage equalization unit.

The control signal generation unit may include a first delay section configured to delay the power-up signal by a first delay time; a second delay section configured to delay an output signal of the first delay section by a second delay time; and an output section configured to output the control signal in response to an output signal of the first delay section and an output signal of the second delay section.

The first delay section may delay a deactivation time of the power-up signal and outputs the delayed signal.

The first delay time may correspond to a certain time at which the control signal is deactivated.

The second delay time may correspond to a pulse width of the control signal after the power-up operation.

The fuse may be connected in a static structure.

In accordance with another exemplary embodiment of the present invention, a repair control circuit includes a plurality of storage units each including the fuse circuit, and configured to latch and output address information programmed in a corresponding fuse in response to a fuse reset signal and equalize both ends of the fuse to the same voltage in response to a control signal, a plurality of address comparison units configured to compare a plurality of address information signals outputted by the plurality of address storage units with a plurality of external address information signals, and output a plurality of comparison result signals, and a repair detection unit configured to output a repair signal in response to the plurality of comparison result signals.

The fuse circuit may include a fuse driving unit configured to drive an output terminal in response to a fuse reset signal, depending on data programmed in a fuse; a separation/connection unit disposed between the fuse and the output terminal and configured to separate or connect the fuse from or to the output terminal in response to a control signal; a voltage equalization unit configured to equalize both ends of the fuse to the same voltage in response to the control signal; and a latching unit configured to latch and output a signal of the output terminal driven by the fuse driving unit.

Each of the address comparison units may include a first transmission unit configured to output the corresponding external is address information signal among the plurality of external address information signals without any modification, in response to the corresponding address information signal among the plurality of address information signals; and a second transmission unit configured to invert and output the corresponding external address information signal in response to the corresponding address information signal.

The fuse circuit may include a row address programmed therein, the row address corresponding to a repair target memory cell.

In accordance with yet another exemplary embodiment of the present invention, a method for driving a fuse circuit includes transmitting information programmed in a fuse to an output terminal after a power-up operation, separating the fuse from the output terminal in response to a control signal, and equalizing both ends of the fuse to the same voltage in response to the control signal.

The method may further include precharging and initializing the output terminal during the power-up operation.

The method may further include separating the fuse from the output terminal before the transmitting of the information.

The method may further include latching and outputting the information transmitted to the output terminal.

A first operation period corresponding to the separating of the fuse may not overlap with a second operation period corresponding to the equalizing of both ends of the fuse.

The fuse may include a row address programmed therein, the row address corresponding to a repair target memory cell.

### BRIEF DESCRIPTION OF THE DRAWINGS

FIG. 1 is a circuit diagram illustrating a known fuse circuit.

FIG. 2 is a timing diagram illustrating the operation of the fuse circuit of FIG. 1.

FIG. 3 is a circuit diagram illustrating a fuse circuit in accordance with an exemplary embodiment of the present invention.

FIG. 4 is a diagram illustrating a control signal generation unit which generates a control signal CTR of FIG. 3.

FIG. 5 is a timing diagram illustrating an operation of the control signal generation unit of FIG. 4.

FIG. 6 is a timing diagram illustrating an operation of the fuse circuit of FIG. 3.

FIG. 7 is a waveform diagram illustrating first and second control signals CTR1 and CTR2 outputted by first and second delay units 350A and 350B of FIG. 3.

FIG. 8 is a circuit diagram illustrating a repair control circuit to which the fuse circuit of FIG. 3 is applied.

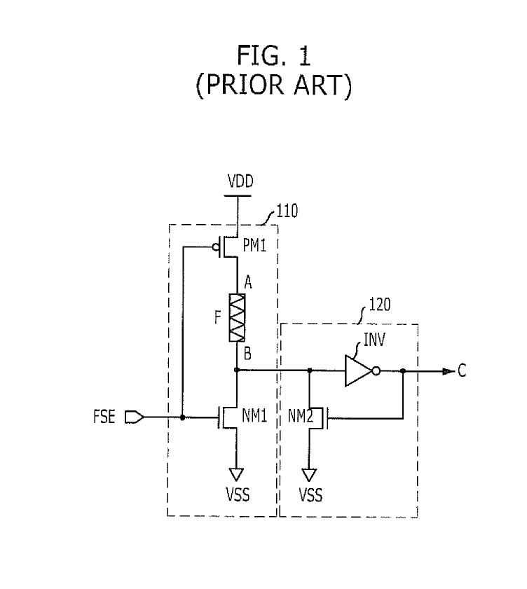

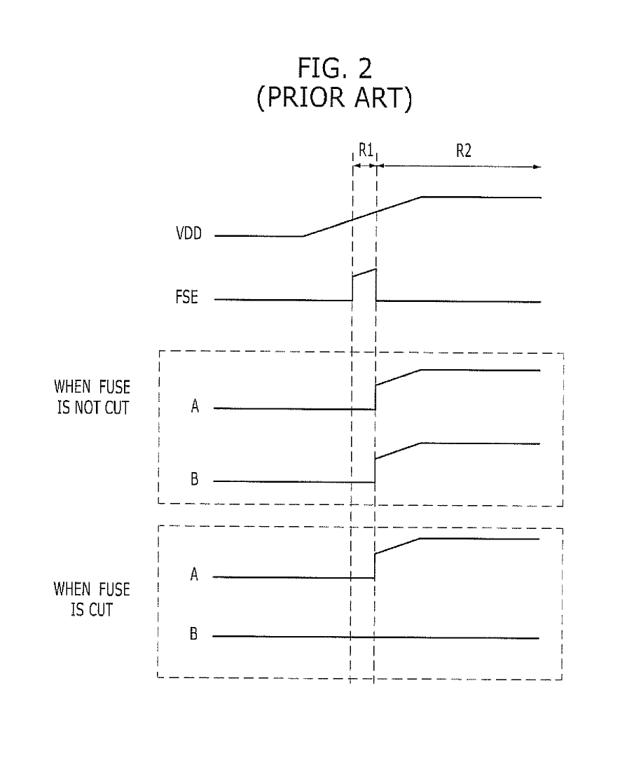

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

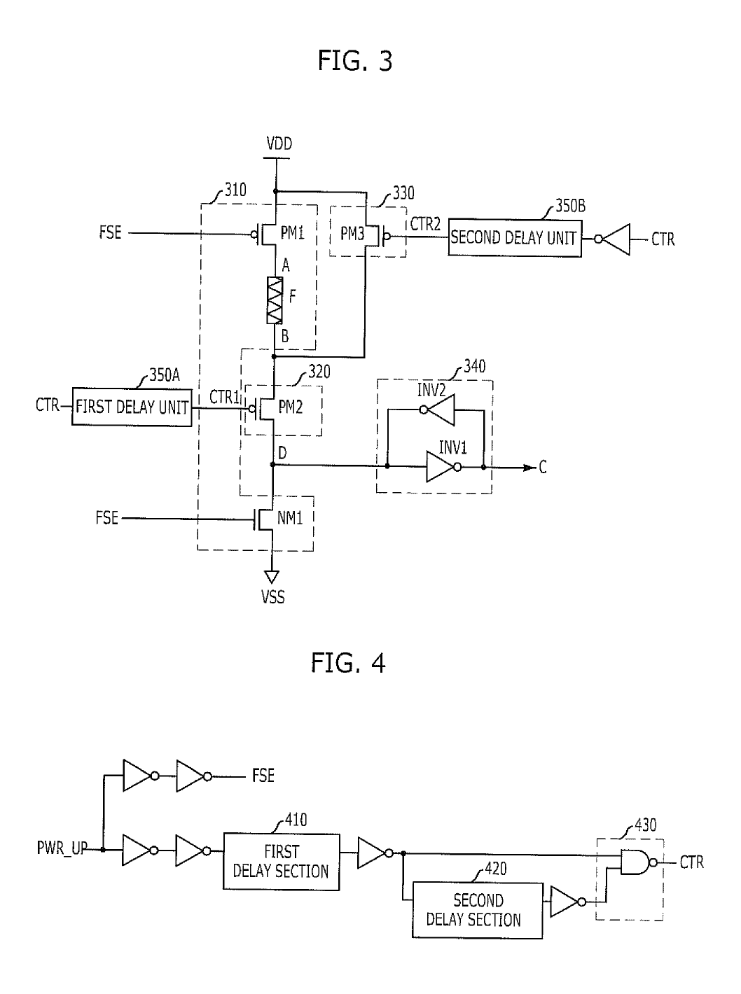

FIG. 3 is a circuit diagram illustrating a fuse circuit in accordance with an exemplary embodiment of the present invention.

Referring to FIG. 3, the fuse circuit includes a fuse driving unit 310, a separation/connection unit 320, a voltage equalization unit 330, a latching unit 340, and first and second delay units 350A and 350B.

The fuse driving unit 310 serves to drive a second node B in response to a fuse reset signal FSE, depending on data programmed in a fuse F. The fuse driving unit 310 includes a first PMOS transistor PM1, the fuse F, and a first NMOS transistor NM1. The first PMOS transistor PM1 has a source-drain path formed between a power supply voltage (VDD) terminal and a first node A, and is configured to receive the fuse reset signal FSE through a gate thereof. The fuse F is connected between the first node A and a second node B. The first NMOS transistor NM1 has a source-drain path formed between a fourth node D and a ground voltage (VSS) terminal, and is configured to receive the fuse reset signal FSE through a gate thereof. As described below, the fuse driving unit 310 drives the fourth node D, when a second PMOS transistor PM2 is turned on.

The separation/connection unit 320 serves to separate or connect the fuse F from or to the fourth node D in response to a control signal CTR. The separation/connection unit 320 includes the second PMOS transistor PM2 having a source-drain path formed between the second node B and the fourth node D and configured to receive the control signal CTR through a gate thereof.

The voltage equalization unit 330 serves to equalize both ends of the fuse F to the same voltage in response to the control signal CTR. The voltage equalization unit 330 includes a third PMOS transistor PM3 having a source-drain path formed between the power supply voltage (VDD) terminal and the second node B and configured to receive the control signal CTR through a gate thereof.

The latching unit 340 serves to latch data driven in the fourth node D and outputs the latched data to a third node C. The latching unit 340 includes a first inverter INV1 and a second inverter INV2. The first inverter INV1 is configured to receive and invert the signal of the fourth node D and to output the inverted signal to the third node C, and the second inverter INV2 is configured to receive and invert the signal of the third node C and to output the inverted signal to the fourth node D.

The first delay unit 350A is configured to delay the control signal CTR and to output a first control signal CTR1 for controlling the separation/connection unit 320. The second delay unit 350B is configured to invert and delay the control signal CTR to output a second control signal CTR2 for controlling the voltage equalization unit 330. As described below, the first delay unit 350A receives the control signal CTR and outputs the first control signal CTR1 in which a deactivation time, corresponding to a connection operation of the separation/connection unit 320, is delayed. Further, as described below, the second delay unit 350B receives the control signal CTR and outputs the second control signal CTR2 in which a deactivation time, corresponding to an equalization operation for both ends of the fuse F, is delayed.

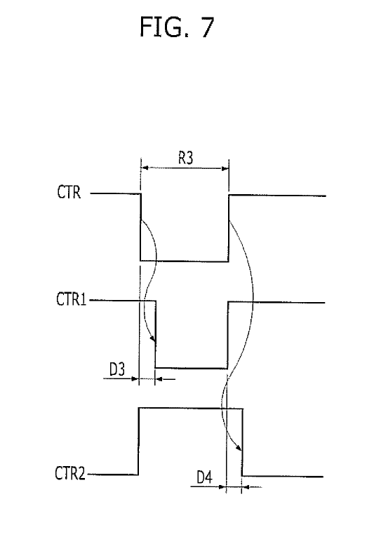

Thus, the fuse circuit in accordance with an exemplary embodiment of the present invention additionally includes the separation/connection unit 320, the voltage equalization unit 330, the latching unit 340, and the first and second delay units 350A and 350B, compared with an existing fuse circuit. For convenience, the first and second delay units 350A and 350B are described below with reference to FIG. 7.

FIG. 4 is a diagram illustrating a control signal generation unit which generates the control signal CTR of FIG. 3.

Referring to FIG. 4, the control signal generation unit serves to generate the control signal CTR in response to a power-up signal PWR_UP, which is activated during a power-up operation, and includes a first delay section 410, a second delay section 420, and an output section 430. For convenience, the description of inverters which perform a buffering operation and an inverting operation on signals will be omitted.

The first delay section 410 is configured to delay the power-up signal PWR_UP, which is activated during the power-up operation, by a first delay time and output the delayed signal. The second delay section 420 is configured to delay the output signal of the first delay section 410 by a second delay time and output the delayed signal. The output section 430 is configured to output the control signal CTR in response to the output signal of the first delay section 410 and the output signal of the second delay section 420. As described below, the first delay section 410 delays and outputs a deactivation time of the power-up signal PWR_UP. The fuse reset signal FSE is a signal which is activated to a certain pulse width during the power-up operation, and is almost the same signal as the power-up signal PWR_UP.

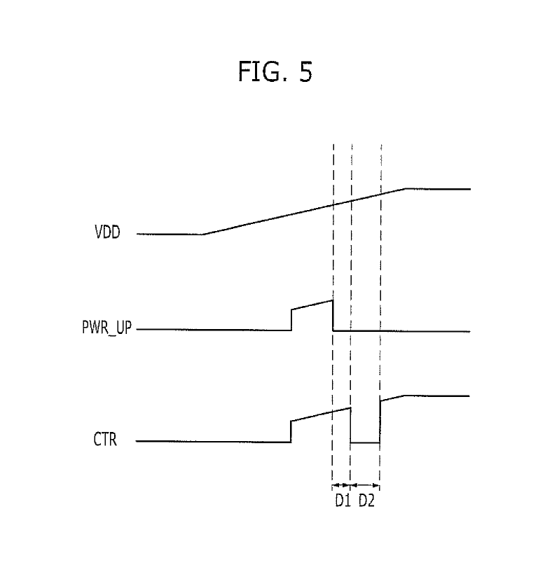

FIG. 5 is a timing diagram illustrating a circuit operation of the control signal generation unit of FIG. 4. For reference, the fuse reset signal FSE is almost the same signal as the power-up signal PWR_UP and has a certain pulse width.

Referring to FIGS. 4 and 5, the power supply voltage VDD is power applied from outside the semiconductor memory device, and rises to a voltage level with a constant slope when the semiconductor memory device is driven for the first time. Although not illustrated in the drawings, the power-up signal PWR_UP is deactivated when the power supply voltage VDD rises to a certain voltage level or more, and the fuse reset signal FSE has a certain pulse width in response to the power-up signal PWR_UP.

The first delay section 410 delays the power-up signal PWR_UP by the first delay time D1, and outputs the delayed signal. At this time, the first delay section 410 delays a deactivation time of the power-up signal PWR_UP (i.e., a point of time when the power-up signal PWR_UP changes to logic ‘low’) by the first delay time D1, and outputs the delayed signal. In other words, a deactivation time of the control signal CTR (i.e., a point of time when the control signal CTR changes from logic ‘high’ to logic ‘low’) corresponds to a point of time at which the first delay time D1 is added after the deactivation time of the power-up signal PWR_UP.

The second delay section 420 delays the outputted signal of the first delay section 410 by the second delay time D2 and outputs a second delayed signal. Then, the output section 430 outputs the pulse-type control signal CTR in response to the output signals of the first and second delay sections 410 and 420. The output section 430 may, for example, include a NAND gate for combining the output signal of the first delay section 410 and the output signal of the second delay section 420 to produce the control signal CT. At this time, the control signal CTR has a pulse width corresponding to the second delay time D2 reflected by the second delay section 420.

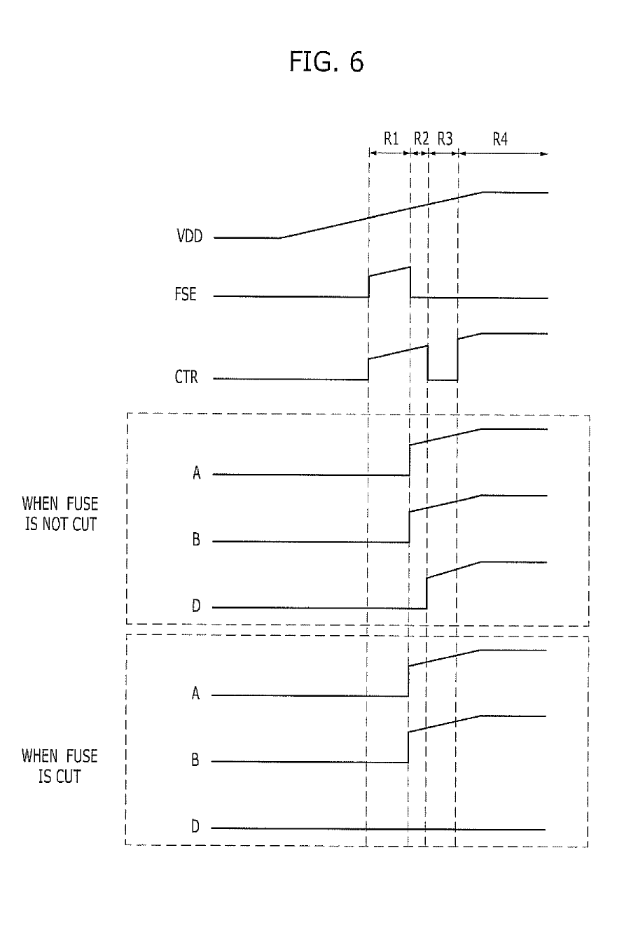

FIG. 6 is a timing diagram illustrating the operation of the fuse circuit of FIG. 3.

Referring to FIGS. 3 to 6, the states of the first node A, the second node B, and the fourth node D, when the fuse F is not cut and when the fuse F is cut, respectively, are described below. For reference, the circuit operation in accordance with an exemplary embodiment of the present invention may be divided into an initialization period R1, a first separation period R2, a data transmission period R3, and a second separation period R4.

First, the case in which the fuse F is not cut is described.

In the initialization period R1, the first NMOS transistor NM1 is turned on and the first PMOS transistor PM1 is turned off in response to the fuse reset signal FSE. Therefore, the fourth node D is precharged to the ground voltage VSS, and the latching unit 340 latches the signal of the fourth node D through the first and second inverters INV1 and INV2. That is, the fourth node D becomes logic ‘low’.

In the first separation period R2, the first NMOS transistor NM1 is turned off and the first PMOS transistor PM1 is turned on in response to the fuse reset signal FSE. At this time, since the fuse F is not cut, the first and second nodes A and B are driven to the power supply voltage VDD. At this time, since the control signal CTR maintains logic ‘high’, the second PMOS transistor PM2 is turned off. Therefore, the fourth node D maintains logic ‘low’.

In the first separation period R2 in accordance with the embodiment of the present invention, the second node B and the fourth node D are separated to prevent a direct current path from being formed between the power supply voltage (VDD) terminal and the ground voltage (VSS) terminal. In the known fuse circuit, since the direct current path is formed at the point of time when the fuse reset signal FSE changes to logic ‘low’, unnecessary power consumption occurs. In this exemplary embodiment of the present invention, however, the second PMOS transistor PM2 is turned off at the point of time when the fuse reset signal FSE changes to logic ‘low’. Therefore, the direct current path between the power supply voltage (VDD) terminal and the ground voltage (VSS) terminal may be prevented from being formed.

In the data transmission period R3, the second PMOS transistor PM2 is turned on and the third PMOS transistor PM3 is turned off in response to the control signal CTR. At this time, the fourth node D is driven to the power supply voltage VDD, and the first and second inverters INV1 and INV2 latch the signal of the fourth node D, which is output to the node C. The control signal CTR has a certain pulse width. In this case, the pulse width may maintain a time during which information indicating that the fuse F is not cut is transmitted to the fourth node D.

In the second separation period R4, the second PMOS transistor PM2 is turned off and the third PMOS transistor PM3 is turned on in response to the control signal CTR. Therefore, the first and second nodes A and B receive the same power supply voltage VDD. That is, the first and second nodes A and B which are both ends of the fuse F are equalized to the same voltage.

When the fuse F is not cut, the fourth node D maintains logic ‘high’, and the third node C outputs logic ‘low’ which is the information indicating that the fuse F is not cut. At this time, since the fourth node D is separated from the second node B, the fourth node D needs to maintain logic ‘high’. Therefore, the fuse circuit in accordance with an exemplary embodiment of the present invention adopts a structure in which the first and second inverters INV1 and INV2 are provided to latch the signal of the fourth node D.

Next, the case where the fuse is cut is described. The initialization period R1 and the first separation period R2 in the case where the fuse F is cut are similar to those in the case where the fuse F is not cut. Therefore, the descriptions thereof will be omitted for convenience.

In the data transmission period R3, the second PMOS transistor PM2 is turned on and the third PMOS transistor PM3 is turned off in response to the control signal CTR. At this time, since the fuse F is cut, the fourth node D maintains logic ‘low’, and the latching unit 340 latches the logic ‘low’. Therefore, the third node C outputs logic ‘high’ which is the information indicating that the fuse F is cut.

In the second separation period R4, the second PMOS transistor PM2 is turned off and the third PMOS transistor PM3 is turned on in response to the control signal CTR. Therefore, the first node A and the second node B receive the same power supply voltage VDD. That is, the first and second nodes A and B which are both ends of the fuse F are equalized to the same voltage. In this embodiment, when the fuse F is cut, both ends of the fuse F are equalized to the same voltage, which makes it possible to prevent a fail from occurring in the fuse F.

Meanwhile, the operation periods of the separation/connection unit 320 and the voltage equalization unit 330 may not overlap each other. That is, the connection operation period of the separation/connection unit 320 and the equalization operation period of the voltage equalization unit 330 may not overlap each other. When the operation periods overlap each other, the equalization operation of the voltage equalization unit 330 is performed during the connection operation of the separation/connection unit 320, which makes it difficult to precisely transmit the information regarding whether the fuse F is cut or not to the fourth node D. In order to address this concern, the first and second delay sections 350A and 350B are additionally provided in an exemplary embodiment of the present invention.

FIG. 7 is a waveform diagram illustrating the first and second control signals CTR1 and CTR2 outputted by the first and second delay units 350A and 3508 of FIG. 3.

Referring to FIGS. 3 and 7, the first delay section 350A delays the point of time when the control signal CTR changes to logic ‘low’ by a delay time D3, and outputs the first control signal CTR1. Additionally, the second delay section 350B delays the point of time when the control signal CTR changes to logic ‘high’ by a delay time D4, and outputs the second control signal CTR2. In other words, the first control signal CTR1 is a signal in which the deactivation time, corresponding to the connection operation of the separation/connection unit 320, is delayed in comparison to the control signal CTR. The second control signal CTR2 is a signal in which the deactivation time, corresponding to the equalization operation of the voltage equalization unit 330, is delayed in comparison to the control signal CTR. Therefore, the period in which the first control signal CTR1 is logic ‘low’, and in which the second node B and the fourth node D are connected, does not overlap the period in which the second control signal CTR2 is logic ‘low’, and in which both ends of the fuse F are equalized.

As described above, the fuse circuit in accordance with an exemplary embodiment of the present invention may transmit the information on whether the fuse F is cut or not to the latching unit 340, after the power-up operation, and equalize both ends of the fuse F to the same voltage, after the fuse F and the fourth node D are separated form each other. Therefore, since both ends of the cut fuse F are driven to the same voltage, a fuse fail can be avoided.

Meanwhile, semiconductor memory devices include a large number of memory cells. As the process technology develops, the integration degree thereof is gradually increasing, and the number of memory cells is also gradually increasing. When a fail occurs in any one of the memory cells, the corresponding semiconductor memory device does not perform a desired operation and is then discarded. Recently, as the process technology of the semiconductor memory device develops, it is highly likely that a fail occurs only in a small number of memory cells. When the corresponding semiconductor memory device, in which a fail occurred in a few memory cells, is discarded as a defective product, the product yield may be undesirable. Therefore, semiconductor memory devices may include redundancy memory cells in addition to normal memory cells in order to address such a defect. In such semiconductor memory devices, when a fail occurs in a normal memory cell, the normal memory cell is replaced with a redundancy memory cell. Hereafter, a memory cell which should be replaced with a redundancy memory cell because of a fail is referred to as a repair target memory cell.

Semiconductor memory devices may include a repair control circuit configured to replace such a repair target memory cell with a redundancy memory cell, when the repair target memory cell is accessed. Such a repair control circuit may be divided into a row repair control circuit and a column repair control circuit, depending on circuit operations. Since the row repair control circuit may have a static structure, the fuse circuit in accordance with the exemplary embodiment of the present invention may be applied.

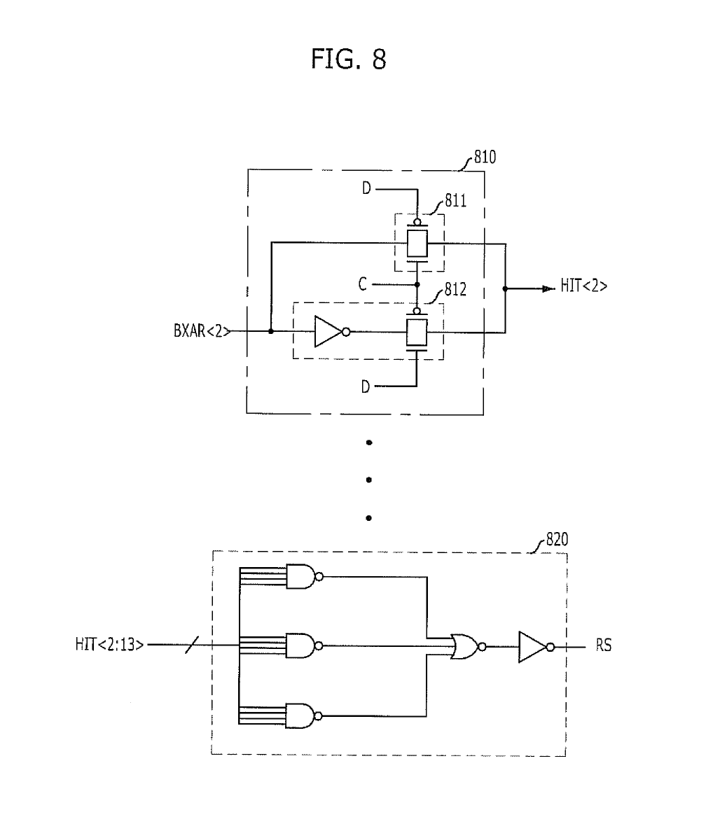

FIG. 8 is a circuit diagram illustrating a repair control circuit to which the fuse circuit of FIG. 3 is applied.

Referring to FIGS. 3 and 8, the repair control circuit includes a plurality of address storage units (not illustrated), a plurality of address comparison units 810 corresponding to the respective address storage units, and a repair detection unit 820. Each of the address storage units includes the fuse circuit of FIG. 3. The fuse F provided in each of the address storage units stores row address information corresponding to a repair target memory cell.

Each of the address storage units latches the row address information programmed in the corresponding fuse F in response to the fuse reset signal FSE, and outputs the latched row address information. As described above, both ends of the corresponding fuse F are equalized to the same voltage in response to the control signal CTR.

Each of the address comparison units 810 serves to invert and output external row address information BXAR<2> in response to output signals of third and fourth nodes C and D of the corresponding address storage unit, or output the external row address information BXAR<2> as it is. The address comparison unit 810 includes first and second transmission sections 811 and 812. The logic levels of the third and fourth nodes C and D are determined depending on whether the fuse F is cut or not. That is, the logic levels of the third and fourth nodes C and D are determined based upon the address information programmed in the fuse F.

The first transmission section 811 outputs the external row address information BXAR<2> as it is, in response to the output signals of the third and fourth nodes C and D. The second transmission section 812 inverts and outputs the external row address information BXAR<2> in response to the output signals of the third and fourth nodes C and D.

Hereafter, the circuit operation of the address comparison unit 810 will be described. For convenience, it is assumed that when a row address corresponding to a repair target memory cell is ‘1’, the fuse F is cut, and when the row address is ‘0’, the fuse F is not cut.

When the fuse F is cut, that is, when the row address corresponding to the repair target memory cell is ‘1’, the fourth node D becomes logic ‘low’, and the third node C becomes logic ‘high’. Therefore, the first transmission section 811 is activated. Accordingly, when the external row address information BXAR<2> is ‘0’, a comparison result signal HIT<2> becomes ‘0’. When the external row address information BXAR<2> is ‘1’, the comparison result signal HIT<2> becomes T.

When the fuse F is not cut, that is, when the row address corresponding to the repair target memory cell is ‘0’, the fourth node D becomes logic ‘high’, and the third node C becomes logic ‘low’. Therefore, the second transmission unit 812 is activated. Accordingly, when the external row address information BXAR<2> is ‘0’, the comparison result signal HIT<2> becomes ‘1’. When the external row address information BXAR<2> is ‘1’, the comparison result signal HIT<2> becomes ‘0’.

When the comparison result signal HIT<2> is ‘0’, it means that the address information programmed in the fuse F (i.e., the row address information corresponding to the repair target memory cell) is different from the external row address information BXAR<2>. On the other hand, when the comparison result signal HIT<2> is ‘1’, it means that the address information programmed in the fuse F is identical to the external row address information BXAR<2>.

FIG. 8 illustrates one address comparison unit 810 among the plurality of address comparison units 810. Here, for example, the plurality of address comparison units output a plurality of comparison result signals HIT<2:13> through the above-described operation. In other words, the plurality of address comparison units may compare the plurality of address information signals outputted depending on whether the fuses F, provided in the respective address storage units, are cut or not with the plurality of external row address information signals applied from outside, and output the plurality of comparison result signals HIT<2:13>.

Meanwhile, the repair detection unit 820 serves to output a repair signal RS in response to the plurality of comparison result signals HIT<2:13>, and includes a logic operation gate. The repair signal RS becomes logic ‘low’ when the plurality of comparison result signals HIT<2:13> are all ‘1’, and becomes logic ‘high’ when any one of the comparison result signals HIT<2:13> is ‘0’. When the repair signal RS is logic ‘low’, it means that the row address information programmed in the respective fuses F coincides with the plurality of external row address information signals. When the repair signal RS is logic ‘high’, it means that the row address information programmed in the respective fuses F does not coincide with the plurality of external row address information signals.

When the external row address information accesses the repair target memory cell using the repair signal RS generated in such a manner as described above, the semiconductor memory device performs a repair operation of replacing the repair target memory cell with a redundancy memory cell.

As described above, the repair control circuit to which the fuse circuit, in accordance with an exemplary embodiment of the present invention, is applied uses a fuse to program address information corresponding to a repair target memory cell. At this time, when a fail occurs in the fuse, it is difficult to perform a desired repair operation. However, when the repair control circuit in accordance with an exemplary embodiment of the present invention is used, a fuse fail does not occur. Therefore, a desired repair operation may be performed, which makes it possible to increase the reliability of the semiconductor memory device.

In accordance with an exemplary embodiment of the present invention, it is possible to prevent a fail from occurring in a fuse. Therefore, it is possible to increase the reliability of a semiconductor memory device including the fuse.

Furthermore, since a direct current path is not formed during the circuit operation, it is possible to prevent unnecessary power consumption.

While the present invention has been described with respect to the specific embodiments, it will be apparent to those skilled in the art that various changes and modifications may be made without departing from the spirit and scope of the invention as defined in the following claims.

What is claimed is:

1. A fuse circuit, comprising:
a fuse driving unit configured to drive an output terminal in response to a fuse reset signal, depending on data programmed in a fuse;
a separation/connection unit disposed between the fuse and the output terminal and configured to separate or connect the fuse from or to the output terminal in response to a control signal;
a voltage equalization unit configured to equalize both ends of the fuse to the same voltage in response to the control signal; and
a latching unit configured to latch and output a signal of the output terminal driven by the fuse driving unit.

2. The fuse circuit of claim 1, further comprising a control signal generation unit configured to generate the control signal in response to a power-up signal which is activated during a power-up operation.

3. The fuse circuit of claim 1, wherein the control signal has a certain pulse width after a power-up operation.

4. The fuse circuit of claim 1, wherein the control signal is deactivated at a certain time after the power-up operation.

5. The fuse circuit of claim 1, wherein a first period corresponding to the connection operation of the separation/connection unit does not overlap with a second period corresponding to the equalization operation of the voltage equalization unit.

6. The fuse circuit of claim 1, further comprising:
a first delay unit configured to delay the control signal to output a first control signal for controlling the separation/connection unit; and
a second delay unit configured to delay the control signal to output a second control signal for controlling the voltage equalization unit.

7. The fuse circuit of claim 6, wherein the first delay unit receives the control signal and delays a deactivation time corresponding to the connection operation of the separation/connection unit, and the second delay unit receives the control signal and delays a deactivation time corresponding to the equalization operation of the voltage equalization unit.

8. The fuse circuit of claim 2, wherein the control signal generation unit comprises:
a first delay section configured to delay the power-up signal by a first delay time;
a second delay section configured to delay an output signal of the first delay section by a second delay time; and
an output section configured to output the control signal in response to an output signal of the first delay section and an output signal of the second delay section.

9. The fuse circuit of claim 8, wherein the first delay section delays a deactivation time of the power-up signal and outputs the delayed signal.

10. The fuse circuit of claim 8, wherein the first delay time corresponds to a certain time at which the control signal is deactivated.

11. The fuse circuit of claim 8, wherein the second delay time corresponds to a pulse width of the control signal after the power-up operation.

12. The fuse circuit of claim 1, wherein the fuse is connected in a static structure.

13. A repair control circuit comprising:
a plurality of storage units each comprising a fuse circuit, and configured to latch and output address information programmed in the corresponding fuse circuit in response to a fuse reset signal and equalize both ends of the fuse to the same voltage in response to a control signal.

14. The repair control circuit of claim 13, further comprising:
a plurality of address comparison units configured to compare a plurality of address information signals outputted by the plurality of address storage units with a plurality of external address information signals, and output a plurality of comparison result signals; and
a repair detection unit configured to output a repair signal in response to the plurality of comparison result signals.

15. The repair control circuit of claim 13, wherein the fuse circuit comprises:
a fuse driving unit configured to drive an output terminal in response to a fuse reset signal, depending on data programmed in a fuse;
a separation/connection unit disposed between the fuse and the output terminal and configured to separate or connect the fuse from or to the output terminal in response to a control signal;
a voltage equalization unit configured to equalize both ends of the fuse to the same voltage in response to the control signal; and
a latching unit configured to latch and output a signal of the output terminal driven by the fuse driving unit.

16. The repair control circuit of claim 15, wherein each of the address comparison units comprises:
a first transmission unit configured to output the corresponding external address information signal among the plurality of external address information signals without any modification, in response to the corresponding address information signal among the plurality of address information signals; and
a second transmission unit configured to invert and output the in corresponding external address information signal in response to the corresponding address information signal.

17. The repair control circuit of claim 15, wherein the fuse circuit comprises a row address programmed therein, the row address corresponding to a repair target memory cell.

18. A method for driving a fuse circuit, comprising:
transmitting information programmed in a fuse to an output terminal after a power-up operation;
separating the fuse from the output terminal in response to a control signal; and
equalizing both ends of the fuse to the same voltage in response to the control signal.

19. The method of claim 18, further comprising precharging and initializing the output terminal during the power-up operation.

20. The method of claim 18, further comprising separating the fuse from the output terminal before the transmitting of the information.

21. The method of claim 18, further comprising latching and outputting the information transmitted to the output terminal.

22. The method of claim 18, wherein a first operation period corresponding to the separating of the fuse does not overlap with a second operation period corresponding to the equalizing of both ends of the fuse.

23. The method of claim 18, wherein the fuse comprises a row address programmed therein, the row address corresponding to a repair target memory cell.
